(19) United States
(12) Patent Application Publication
(10) Pub. No.: US 2026/0175548 A1
(43) Pub. Date: Jun. 25, 2026

(54) SHEET, METHOD FOR PRODUCING THE SAME, METAL-CLAD LAMINATE, CIRCUIT BOARD, AND ANTENNA

(71) Applicant: DAIKIN INDUSTRIES, LTD., Osaka (JP)

(72) Inventors: Shingo OKUNO, Osaka (JP); Hotaru YAMAGUCHI, Osaka (JP); Kyohei SAWAKI, Osaka (JP); Moe FUJISHIRO, Osaka (JP); Yoshito TANAKA, Osaka (JP)

(73) Assignee: DAIKIN INDUSTRIES, LTD., Osaka (JP)

(21) Appl. No.: 19/545,263

(22) Filed: Feb. 20, 2026

Related U.S. Application Data
(63) Continuation of application No. PCT/JP2024/031602, filed on Sep. 3, 2024.

(30) Foreign Application Priority Data
Sep. 8, 2023 (JP) 2023-145818

(51) Int. Cl. B32B 27/32; B32B 15/085; B32B 15/20; B32B 27/20; H01Q 1/28; H05K 1/03

(52) U.S. Cl. CPC B32B 27/322; B32B 15/085; B32B 15/20; B32B 27/20; H05K 1/0373; B32B 2250/02; B32B 2264/1021; B32B 2264/1023; B32B 2264/303; B32B 2307/204; B32B 2311/12; B32B 2457/08; H01Q 1/28; H05K 2201/015; H05K 2201/0209; H05K 2201/0242

(57) ABSTRACT

A sheet with a small change in relative dielectric constant due to change in temperature, is provided. The sheet having a rate of change in relative dielectric constant of 0.020 or less within the temperature range of −50 to 150° C.

### CROSS-REFERENCE TO RELATED APPLICATIONS

This application is a Rule 53(b) Continuation of International Application No. PCT/JP2024/031602 filed Sep. 3, 2024, which claims priority based on Japanese Patent Application No. 2023-145818 filed Sep. 8, 2023, the respective disclosures of which are incorporated herein by reference in their entirety.

### TECHNICAL FIELD

The present disclosure relates to a sheet, a method for producing the same, a metal-clad laminate, a circuit board, and an antenna.

### BACKGROUND ART

In high-frequency printed wiring boards, those with a low transmission loss have been demanded. In such high-frequency printed wiring boards, particularly, substrates to be used in antennas for millimeter wave radars for mobility are required to have a minimal change in relative dielectric constant due to change in temperature.

Patent Literatures 1 to 3 disclose the use of two or more of fillers in combination with a fluororesin as an electronic substrate material.

### CITATION LIST

### Patent Literature

Patent Literature 1: Japanese Patent Laid-Open No. 2020-050860
Patent Literature 2: Japanese Patent Laid-Open No. 2020-037662
Patent Literature 3: Japanese Patent Laid-Open No. 2023-028091

### SUMMARY

The present disclosure is a sheet comprising two or more fillers, wherein a rate of change in relative dielectric constant is 0.020 or less in a temperature range of −50 to 150° C.

### DESCRIPTION OF EMBODIMENTS

The present disclosure will be described in detail below.

The present disclosure is a sheet characterized in that the rate of change in relative dielectric constant is 0.020 or less in the temperature range of −50 to 150° C. In other words, the relative dielectric constant remains constant over the wide temperature range of −50 to 150° C. This minimizes changes in the electrical properties of the sheet.

In recent years, there has been an increase in finely formed circuits, such as those used in millimeter wave radar antennas. In such circuits, even a slight change in relative dielectric constant can alter the electrical properties, as a result of which an operational malfunction may occur.

Communication in fields of mobility applications requires its high degree of accuracy. Therefore, using a sheet with a relative dielectric constant that remains almost constant in the aforementioned wide temperature range can eliminate malfunctions in communication.

In other fields as well, densification and wiring thinning of wiring boards have progressed, so that it has been increasingly important to reduce the rate of change in relative dielectric constant in order not to cause operational malfunction. The present disclosure aims to address this issue, which has not been achieved by conventional technology. It is to be noted that the rate of change in relative dielectric constant as disclosed herein is the value measured using the method described in Examples.

The rate of change in relative dielectric constant in the temperature range of −50 to 150° C. is preferably 0.020 or less, more preferably 0.018 or less, and still more preferably 0.016 or less. Also, the lower limit is not limited but can be, for example, 0.001 or more.

The sheet of the present disclosure preferably has a coefficient of linear expansion (CTE) of 70 ppm/° C. or less. The sheet with such a low coefficient of linear expansion is advantageous in that it provides excellent dimensional stability and stable performance even when used under conditions of a large temperature change. The CTE is more preferably 50 ppm/° C. or less and still more preferably 40 ppm/° C. or less. The lower limit of the CTE is not limited, but is preferably 10 ppm/° C. or more and more preferably 18 ppm/° C.

The sheet of the present disclosure preferably has a dielectric loss tangent value at 10 GHz of 0.0015 or less. The sheet thus obtained is preferred in term of its low dielectric loss and reduced loss. The dielectric loss tangent is the value measured at 20° C. and is more specifically the value measured by the method described in Examples.

The dielectric loss tangent at 10 GHz is more preferably 0.0012 or less and still more preferably 0.0011 or less. The lower limit of the dielectric loss tangent at 10 GHz is not limited but can be, for example, 0.00001 or more.

The sheet preferably has a thickness of 5 to 250 μm. Within the aforementioned range of the thickness, the sheet can be suitably used in a metal-clad laminate. The sheet of the present disclosure can sufficiently achieve its purpose even though it is thin. The thickness is more preferably less than 230 μm and still more preferably less than 200 μm. Furthermore, the thickness is more preferably more than 15 μm and still more preferably more than 30 μm.

The composition of the sheet of the present disclosure is not limited but is preferably those containing a resin and a filler. The sheet having such a composition can provide the aforementioned specific physical properties. The resin and filler will be described in detail below.

### (Fluororesin)

The composition of the present disclosure contains a fluororesin. The fluororesin has low dielectric properties and can therefore be suitable for use for the purposes of the present disclosure.

The fluororesin as can be used in the present disclosure is not limited, but examples thereof include polytetrafluoroethylene (PTFE), a tetrafluoroethylene [TFE]/hexafluoropropylene [HFP] copolymer [FEP], a TFE/alkyl vinyl ether copolymer [PFA], a TFE/HFP/alkyl vinyl ether copolymer [EPA], a TFE/chlorotrifluoroethylene [CTFE] copolymer, a TFE/ethylene copolymer [ETFE], polyvinylidene difluoride [PVdF], and tetrafluoroethylene with a molecular weight of 300,000 or less [LMW-PTFE]. These may be used singly or two or more thereof may be mixed and used. Polytetrafluoroethylene resin (PTFE) is particularly preferred from the viewpoint of low dielectric properties. The PTFE preferably has fibrillating ability. The PTFE having fibrillating ability means a PTFE that can be extruded in paste form from unsintered polymer powder thereof.

The PTFE may be modified polytetrafluoroethylene (hereinafter referred to as modified PTFE), homopolytetrafluoroethylene (hereinafter referred to as homo-PTFE), or a mixture of modified PTFE and homo-PTFE. It is to be noted that from the viewpoint of favorably maintaining formability of the polytetrafluoroethylene, the proportion of the content of the modified PTFE in polymer PTFE is preferably 10% by mass or more and 98% by mass or less and more preferably 50% by mass or more and 95% by mass or less. The homo-PTFE is not limited, and the following homo-PTFEs can be suitably used, which have been disclosed in Japanese Patent Laid-Open No. 53-60979, Japanese Patent Laid-Open No. 57-135, Japanese Patent Laid-Open No. 61-16907, Japanese Patent Laid-Open No. 62-104816, Japanese Patent Laid-Open No. 62-190206, Japanese Patent Laid-Open No. 63-137906, Japanese Patent Laid-Open No. 2000-143727, Japanese Patent Laid-Open No. 2002-201217, International Publication No. WO 2007/046345, International Publication No. WO 2007/119829, International Publication No. WO 2009/001894, International Publication No. WO 2010/113950, International Publication No. WO 2013/027850, and the like. Among these, homo-PTFEs having a high degree of stretchability are preferred, which have been disclosed in Japanese Patent Laid-Open No. 57-135, Japanese Patent Laid-Open No. 63-137906, Japanese Patent Laid-Open No. 2000-143727, Japanese Patent Laid-Open No. 2002-201217, International Publication No. WO 2007/046345, International Publication No. WO 2007/119829, International Publication No. WO 2010/113950, and the like.

The modified PTFE is composed of TFE and a monomer other than TFE (hereinafter referred to as a modifying monomer). Examples of the modified PTFE include but are not limited to modified PTFE in which PTFE has been uniformly modified with the modifying monomer, modified PTFE in which PTFE has been modified at the beginning of the polymerization reaction, and modified PTFE in which PTFE has been modified at the end of the polymerization reaction. The modified PTFE is preferably a TFE copolymer obtained by subjecting TFE to polymerization with a trace amount of a monomer other than TFE, within a range that does not significantly impair the properties of a TFE homopolymer. The following modified PTFEs can be suitably used, such as those disclosed in, for example, Japanese Patent Laid-Open No. 60-42446, Japanese Patent Laid-Open No. 61-16907, Japanese Patent Laid-Open No. 62-104816, Japanese Patent Laid-Open No. 62-190206, Japanese Patent Laid-Open No. 64-1711, Japanese Patent Laid-Open No. 2-261810, Japanese Patent Laid-Open No. 11-240917, Japanese Patent Laid-Open No. 11-240918, International Publication No. WO 2003/033555, International Publication No. WO 2005/061567, International Publication No. WO 2007/005361, International Publication No. WO 2011/055824, International Publication No. WO 2013/027850, and the like. Among these, preferred are modified PTFEs having a high degree of stretchability, such as those disclosed in Japanese Patent Laid-Open No. 61-16907, Japanese Patent Laid-Open No. 62-104816, Japanese Patent Laid-Open No. 64-1711, Japanese Patent Laid-Open No. 11-240917, International Publication No. WO 2003/033555, International Publication No. WO 2005/061567, International Publication No. WO 2007/005361, International Publication No. WO 2011/055824, and the like.

The modified PTFE includes a TFE unit based on TFE and a modifying monomer unit based on the modifying monomer. The modifying monomer unit is a portion of the molecular structure of the modified PTFE and is derived from the modifying monomer. The modified PTFE preferably contains a modifying monomer unit in an amount of 0.001 to 0.500% by mass and more preferably 0.01 to 0.30% by mass, of the total monomer unit. The total monomer unit is a portion derived from all monomers in the molecular structure of the modified PTFE.

The modifying monomer is not limited as long as it can be copolymerized with TFE, and examples thereof include a perfluoroolefin such as hexafluoropropylene (HFP); a chlorofluoroolefin such as chlorotrifluoroethylene (CTFE); hydrogen-containing fluoroolefins such as trifluoroethylene and vinylidene difluoride (VDF); perfluorovinyl ether; a perfluoroalkylethylene (PFAE), and ethylene. The modifying monomer to be used may be one type or a plural types thereof.

The perfluorovinyl ether is not limited, and examples thereof include an unsaturated perfluoro compound represented by the following general formula (1):

CF₂═CF—ORf (1)

wherein Rf represents a perfluoro organic group.

The perfluoro organic group as used herein is an organic group in which all hydrogen atoms bonded to carbon atoms are replaced with fluorine atoms. The perfluoro organic group may have an ether oxygen.

An example of the perfluorovinyl ether includes a perfluoro (alkyl vinyl ether) (PAVE) in which Rf in the general formula (1) described above is a perfluoroalkyl group having 1 to 10 carbon atoms. The number of carbon atoms in the perfluoroalkyl group is preferably 1 to 5. Examples of the perfluoroalkyl group in a PAVE include a perfluoromethyl group, a perfluoroethyl group, a perfluoropropyl group, a perfluorobutyl group, a perfluoropentyl group, and a perfluorohexyl group. A preferred PAVE is perfluoropropyl vinyl ether (PPVE) and perfluoromethyl vinyl ether (PMVE).

The perfluoroalkyl ethylene (PFAE) is not limited, and examples thereof include perfluorobutyl ethylene (PFBE) and perfluorohexyl ethylene (PFHE).

The modifying monomer in the modified PTFE is preferably at least one selected from the group consisting of HFP, CTFE, VDF, a PAVE, a PFAE and ethylene.

The fluororesin described above is preferably non-melt-processible. The phrase non-melt-processible means that a resin does not have sufficient flowability even when heated at its melting point or higher, and cannot be molded by melt forming techniques commonly used for resins. PTFE corresponds thereto.

In the present disclosure, it is preferable to use such a non-melt-processible fluororesin and form it into a sheet by a forming method for fibrillating it. This forming method will be described later.

The PTFE preferably has an SSG of 2.0 to 2.3. The use of such PTFE facilitates a PTFE film having high strength (cohesion strength and puncture strength per unit thickness) to be obtained. PTFE with a large molecular weight has long molecular chains, making it less likely to form a structure of molecular chains regularly arranged. In this case, an amorphous portion elongates, resulting in an increase in the degree of entanglement between molecules. It is considered that the high degree of entanglement between molecules is less likely to allow a PTFE film to deform under an applied load and therefore to exhibit excellent mechanical strength. Also, using PTFE with a large molecular weight facilitates a PTFE film having a small average pore size to be obtained.

The lower limit of the SSG is more preferably 2.05 and still more preferably 2.1. The upper limit of the SSG is more preferably 2.25 and still more preferably 2.2.

The standard specific gravity [SSG] is measured by fabricating a sample in accordance with ASTM D-4895-89 and measuring the specific gravity of the obtained sample by a water displacement method.

In the present embodiment, the molecular weight (number-average molecular weight) of the PTFE constituting the PTFE powder ranges, for example, from 2 to 12 million. The lower limit value of the molecular weight of the PTFE may be 3 million or 4 million. The upper limit value of the molecular weight of the PTFE may be 10 million.

A method for measuring the number-average molecular weight of the PTFE includes a method for determining the number-average molecular weight using the standard specific gravity (SSG) and a method for determining the number-average molecular weight using a dynamic viscoelasticity upon melting. The method for determining the number-average molecular weight using the standard specific gravity can be performed by a water displacement method in accordance with ASTM D-792 using a sample formed in accordance with ASTM D-4895 98. The method for measuring the number-average molecular weight using a dynamic viscoelasticity is explained, for example, by S. Wu in Polymer Engineering & Science, 1988, Vol. 28, 538 and in the same publication, 1989, Vol. 29, 273.

The PTFE preferably has a refractive index in the range of 1.2 to 1.6. With such a refractive index, the PTFE has a low dielectric constant, which is preferable in this regard. The refractive index can be adjusted to within the range described above by a method of adjusting the polarizability or flexibility of the main chain or the like. The lower limit of the refractive index is more preferably 1.25, more preferably 1.30, and most preferably 1.32. The upper limit of the refractive index is more preferably 1.55, more preferably 1.50, and most preferably 1.45.

The refractive index is the value measured using a refractometer (Abbemat 300).

Also, the PTFE preferably has the maximum endothermic peak temperature (crystalline melting point) of 340±7° C.

The PTFE may be low-melting-point PTFE having the maximum peak temperature of 338° C. or lower on an endothermic curve on a crystalline melting curve measured by a differential scanning calorimeter, or high-melting-point PTFE having the maximum peak temperature of 342° C. or higher on an endothermic curve on a crystalline melting curve measured by a differential scanning calorimeter.

The low-melting-point PTFE is powder produced by a polymerization using an emulsion polymerization method, and has the maximum endothermic peak temperature (crystalline melting point), a dielectric constant (ε) of 2.08 to 2.2, and a dielectric loss tangent (tan δ) of 1.9×10⁻⁴ to 4.0×10⁻⁴. Examples of a commercially available product thereof include POLYFLON Fine Powder F201, F203, F205, F301, and F302 manufactured by Daikin Industries, Ltd.; CD090 and CD076 manufactured by Asahi Glass Co., Ltd.; and TF6C, TF62, and TF40 manufactured by Dupont De Nemours Inc.

The high melting point PTFE powder is also powder produced by a polymerization using an emulsion polymerization method, and has the maximum endothermic peak temperature (crystalline melting point) described above, a dielectric constant (ε) of 2.0 to 2.1, and a dielectric loss tangent (tan δ) of 1.6×10⁻⁴ to 2.2×10⁻⁴, which are overall low. Examples of a commercially available product thereof include POLYFLON Fine Powder F104 and F106 manufactured by Daikin Industries, Ltd.; CD1, CD141, and CD123 manufactured by Asahi Glass Co., Ltd.; and TF6 and TF65 manufactured by DuPont De Nemours Inc.

It is to be noted that an average particle size of powder in which both PTFE polymer particles have undergone secondary aggregation is usually preferably 250 to 2,000 μm. In particular, granulated powder obtained by granulation using a solvent is preferred from the viewpoint of improving flowability when filled in a mold upon preliminary forming.

PTFE in powder form that satisfies the aforementioned parameters can be obtained using conventional production methods. For example, it may be produced by following the production methods described in International Publication No. WO 2015-080291 and International Publication No. WO 2012-086710.

### (Filler)

The filler that can be used in the present disclosure is not limited, and examples thereof include one or more organic fillers selected from an aramid fiber, a polyphenyl ester, polyphenylene sulfide, polyimide, polyether ether ketone, polyphenylene, polyamide, or a wholly aromatic polyester resin; and one or more inorganic fillers selected from ceramics, talc, mica, alumina, tin oxide, titanium oxide, silica, calcium carbonate, calcium oxide, magnesium oxide, zirconium oxide, potassium titanate, a glass fiber, a glass chip, a glass bead, silicon carbide, calcium fluoride, boron nitride, barium sulfate, molybdenum disulfide, or a potassium carbonate whisker. The sheet of the present disclosure uses two or more of these fillers in combination.

Among these, the filler particularly preferably includes at least two selected from the group consisting of silica, alumina, boron nitride, and zirconium oxide.

Changes in temperature of dielectric loss tangent and relative dielectric constant are closely related to the band gap of the filler. Basically, a low dielectric loss tangent can be achieved by using a compound with a large band gap. Therefore, these compounds with a band gap in a suitable range are particularly suitable for use. A preferred band gap range is 2 eV or more, followed by 3 eV or more, 3.5 eV or more, and 4 eV or more in this order. A filler with a band gap of more preferably 4.5 eV or more, still more preferably 5 eV or more, or particularly preferably 6 eV or more, is suitable for use. Also, using two or more of these fillers among these in combination is particularly preferable in terms of rendering of a sheet with a small change in temperature of relative dielectric constant. Among these, the filler is most preferably two of silica and alumina. The band gap of the filler is calculated by measuring a diffuse reflectance spectrum using a UV-Visible Spectrophotometer (UV-2600 manufactured by Shimadzu Corporation). The measurement results are loaded, as spectrum data, into an Excel macro for band gap calculation, and a “photometric value (transmission/reflectance)” and an “n value (type of transition process)” are selected. Then, a range in which the plotted data in the vicinity of an inflection point could be approximated by a straight line as a tangent line is specified to calculate the band gap using a Tauc plot.

When silica is used in combination with alumina, both have a large bandgap of 5 eV or more, so that the combined use thereof can particularly reduce a change in temperature of relative dielectric constant.

When the filler is a combination of silica and alumina, the silica is preferably a spherical silica particle. The silica particle of spherical shape is preferable in terms of facilitating uniform processing upon drilling and having a small specific surface area and a low transmission loss.

The spherical silica particle refers to a particle, the shape of which is close to a perfect sphere. Specifically, the sphericity is preferably 0.80 or more, more preferably 0.85 or more, still more preferably 0.90 or more, and most preferably 0.95 or more. The sphericity is calculated by taking a photograph of the particle with an SEM and calculating a value from an area and an perimeter of the particle observed, by formula: (sphericity)={4π×(area)/(perimeter)²}. The closer the sphericity is to 1, the closer the particle is to a perfect sphere. Specifically, an average value measured for 100 particles is adopted using an image processing device (FPIA-3000 manufactured by Spectris PLC).

The spherical silica particle as used in the present disclosure preferably has a D90/D10 of 2 or more (preferably 2.3 or more, or 2.5 or more) and a D50 of 10 μm or less, when integrating its volume from the smallest particle size. Furthermore, the D90/D50 is preferably 1.5 or more (still more preferably 1.6 or more). The D50/D10 is preferably 1.5 or more (still more preferably 1.6 or more). Furthermore, the D50 is more preferably 5 μm or less. A spherical silica particle with a small particle size can enter a gap between spherical silica particles with a large particle size, allowing excellent filling properties and improved flowability. In particular, the particle size distribution preferably has a higher degree of frequency of particle sizes on the small particle size side compared to a Gaussian curve. The particle size can be measured using a laser diffraction/scattering particle size distribution measurement apparatus. Also, the presence of a coarse particle makes it difficult to form a thin sheet, so that a coarse particle having a particle size above a predetermined size is preferably removed using a filter or the like.

In the present disclosure, a surface area (m²/g) of the filler is a value obtained based on a BET method and can be measured using a “Macsorb HM model-1208” (manufactured by Mountech Co., Ltd.) as a specific surface area measuring apparatus. It is to be noted that when the sheet of the present disclosure contains two or more fillers, the total surface area of all compounded fillers preferably falls within the aforementioned range.

The silica particle described above preferably has an average particle size of 10 μm or less. The average particle size of the silica particles of 10 μm or less reduces the surface roughness of the sheet, which is preferable. The upper limit of the average particle size of the silica particles is more preferably 8 μm or less and still more preferably 5 μm or less. It is to be noted that the average particle size as used herein is the D50 value measured by a laser analysis particle size distribution analyzer.

The silica particle may have been subjected to treatment with a silane coupling agent. Preliminary surface treatment can inhibit aggregation of silica particles, allowing favorable dispersion of the silica particles in the sheet.

The silane coupling agent is not limited, and any publicly known silane coupling agent can be used. Specific examples thereof include treatment with silane coupling agents such as epoxy silane having a reactive functional group, amino silane, isocyanate silane, vinyl silane, acrylic silane, hydrophobic alkyl silane, phenyl silane, and fluorinated alkyl silane, plasma processing, and fluorination treatment.

Examples of the silane coupling agent include epoxy silanes such as γ-glycidoxypropyltriethoxysilane and β-(3,4-epoxycyclohexyl)ethyltrimethoxysilane, amino silanes such as aminopropyltriethoxysilane and N-phenylaminopropyltrimethoxysilane, an isocyanate silane such as 3-isocyanatepropyltrimethoxysilane, a vinyl silane such as vinyltrimethoxysilane, and an acrylic silane such as acryloxytrimethoxysilane. Among these, a silane coupling agent containing an aminopropyl group is preferred.

The spherical silica particle to be used described above may be a commercially available silica particle that satisfies the aforementioned properties. Examples of the commercially available silica particle include DENKA FUSED SILICA FB grade (manufactured by Denka Company Limited), DENKA FUSED SILICA SFP grade (manufactured by Denka Company Limited), EXCELICA (manufactured by Tokuyama Corporation), high-purity synthetic spherical silica particles ADMAFINE (manufactured by Admatechs Co., Ltd.), ADMANANO (manufactured by Admatechs Co., Ltd.), and ADMAFUSE (manufactured by Admatechs Co., Ltd.).

In a case in which the silica particle described above has been treated with a silane coupling agent, the amount treated is not limited but is preferably in the range of 0.1 to 1.5% by mass and more preferably 0.15 to 1.0% by mass based on the amount of coated silica particle.

The alumina described above has favorable electrical insulating properties and thermal conductivity, and the shape and size of an alumina particle is not limited, and any publicly known alumina particle can be used. More specifically, its average particle size is preferably 10 μm or less. An alumina particle with an average particle size of 10 μm or less reduces the surface roughness of the sheet, which is therefore preferred. The upper limit of the average particle size of the alumina particles is more preferably 5 μm or less and still more preferably 4 μm or less. Also, the lower limit of the average particle size of the alumina particles is not limited but is preferably 0.5 μm or more. The average particle size of less than 0.5 μm causes filler aggregation, resulting in a tendency not to provide a sufficient effect. Incidentally, a method for measuring the average particle size here is the same as that for the aforementioned silica particle. The alumina particle may or may not have undergone surface treatment. Also, the BET specific surface area (m²/g) thereof is preferably 1.0 to 5.0, more preferably 1.2 to 4.0, and particularly preferably 1.4 to 3.2. The oil absorption (ml/100 g) is preferably 10 to 40, more preferably 15 to 30, and particularly preferably 20 to 27. The pH of the alumina particle is preferably 7 to 10, more preferably 8 to 10, and particularly preferably 9.

The mixing ratio of the silane particles and alumina particles is not limited, but, for example, the amount of alumina compounded is preferably 10 to 50% by mass based on the total amount of alumina and silica, more preferably 12 to 40% by mass, and still more preferably 13 to 35% by mass. The amounts of both compounded staying within the aforementioned range are preferable in terms of allowing a sheet with a minimal temperature change in relative dielectric constant to be obtained.

The alumina particle to be used described above may be a commercially available alumina particle, which satisfies the aforementioned properties. Examples of the commercially available alumina particle include LS-210B and LS-110F manufactured by Nippon Light Metal Co., Ltd.

The sheet of the present disclosure preferably contains a filler in a proportion of 30% by mass or more based on the total mass of the sheet. Such an amount compounded is preferable in view of achieving low thermal expansion while maintaining a low dielectric constant and low loss. The amount compounded is more preferably 35% by mass or more, still more preferably 50% by mass or more, and yet still more preferably 55% by mass or more. The upper limit of the amount of filler compounded is not limited, and is preferably 70% by mass or less, more preferably 68% by mass or less, and still more preferably 65% by mass or less.

### (Method for Producing Sheet)

The sheet of the present disclosure can be obtained by mixing the aforementioned fluororesin particle and the filler to form a film. The production method is not limited, and paste extrusion forming, powder rolling forming, or the like can be employed.

As described above, it is preferable to use, as the fluororesin to be used in the sheet of the present disclosure, a non-melt-processible fluororesin. When such a fluororesin is used and formed into a sheet, it is preferable to form it into a sheet by fibrillating powdered PTFE as a raw material.

It is preferable to use the powdered PTFE having a primary particle size of 0.05 to 10 μm. Using such powder has an advantage of excellent moldability and dispersibility. It is to be noted that the primary particle size as used herein is a value measured in accordance with ASTM D 4895.

The powdered PTFE contains a polytetrafluoroethylene resin having a secondary particle size of 500 μm or more in an amount of preferably 50% by mass or more and more preferably 80% by mass or more. The PTFE having a secondary particle size of 500 μm or more within the above range, has an advantage of being capable of fabricating a mixture sheet with high strength. Using the PTFE having a secondary particle size of 500 μm or more enables a mixture sheet with lower resistance and greater toughness to be obtained.

The lower limit of the secondary particle size is more preferably 300 μm and still more preferably 350 μm. The upper limit of the secondary particle size is more preferably 700 μm or less and still more preferably 600 μm or less. The secondary particle size can be determined, for example, by a sieving method or the like.

The powdered PTFE described above can provide a sheet with higher strength and excellent homogeneity, so that an average primary particle size thereof is preferably 50 nm or more, more preferably 100 nm or more, still more preferably 150 nm or more, and particularly preferably 200 nm or more. The larger the average primary particle size of PTFE is, the more inhibited an increase in paste extrusion pressure upon paste extrusion forming using the powder will be, also resulting in excellent moldability. The upper limit of the average primary particle size of PTFE is not limited, but it may be 500 nm. From the viewpoint of productivity in a polymerization process, it is preferably 350 nm.

The average primary particle size can be determined by preparing a calibration curve of a transmission of projected light of 550 nm relative to a unit length of an aqueous dispersion obtained by using an aqueous dispersion of PTFE obtained by polymerization and adjusting its polymer concentration to 0.22% by mass, and an average primary particle size determined by measuring an unidirectional diameter of the particle observed in a photograph of the particle by a transmission electron microscope, and then measuring the transmission of the aqueous dispersion to be measured, based on the calibration curve.

The PTFE to be used in the present disclosure may have a core-shell structure. An example of the PTFE having a core-shell structure includes modified polytetrafluoroethylene which contains a core of high molecular weight polytetrafluoroethylene in the particle and a shell of lower molecular weight polytetrafluoroethylene or modified polytetrafluoroethylene. An example of such modified polytetrafluoroethylene includes the polytetrafluoroethylene described in Japanese Translation of PCT International Application Publication No. 2005-527652.

Specific methods of paste extrusion forming and powder rolling forming are not limited, and a general method will be described below.

### (Paste Extrusion Forming)

A method for producing the sheet may include the steps of (1a) mixing PTFE powder obtained using a hydrocarbon surfactant and an auxiliary agent for extrusion, (1b) subjecting the mixture obtained to paste extrusion forming, (1c) rolling the extrudate obtained by extrusion forming, (1d) drying the rolled sheet, and (1e) sintering the dried sheet to obtain a formed article. The paste extrusion forming may also be performed by adding conventionally and publicly known additives such as a pigment or a filler to the PTFE powder.

The auxiliary agent for extrusion is not limited, and any publicly known agent may be used. Examples thereof include hydrocarbon oil and the like.

### (Powder Rolling Forming)

The sheet can also be formed by powder rolling forming. The powder rolling forming is a method for applying shear force to a resin powder followed by fibrillation thereof, and thus forming it into a sheet. This method may include the step of sintering the sheet thereafter to obtain a formed article.

More specifically, the sheet can be obtained by a production method including
step (1) of applying shear force while mixing a raw material composition containing a fluororesin and a filler,
step (2) of forming the mixture obtained by step (1) above into a bulk form, and
step (3) of rolling the mixture in bulk form obtained by step (2) above into a sheet.

It is to be noted that in case of forming a sheet by such powder rolling forming, it is preferable to mix only a fluororesin particle and an inorganic filler to form the sheet.

In the case of a sheet to be produced by the powder rolling forming method, it is preferable to form a film using a composition that is free of a liquid component and is substantially composed of a fluororesin particle and a filler particle. The phrase “substantially composed of a fluororesin particle and a filler particle” means that the content of a component other than the fluororesin particle and filler particle is 3% by mass or less based on the total amount of composition.

The sheets of the present disclosure may have been subjected to surface treatment in order to enhance the adhesion strength with a copper foil. A specific method of the surface treatment of the sheet is not limited, and any known method can be employed. The surface treatment of the sheet can employ conventional discharge treatment such as plasma discharge treatment, corona discharge treatment, glow discharge treatment, and sputtering treatment. Among them, the plasma treatment is suitable.

The plasma treatment is treatment whereby a fluororesin on an outer surface of a sheet is etched by bringing the sheet into contact with plasma, to impart an oxygen atom, a nitrogen atom, and the like to the outer surface of the sheet.

For example, introducing oxygen gas, nitrogen gas, hydrogen gas, helium gas, argon gas, or the like into a discharge atmosphere enables the surface free energy to be controlled.

Alternatively, surface treatment may be carried out by exposing a surface to be modified to an atmosphere of organic compound-containing inert gas, which is inert gas containing an organic compound, applying a high-frequency voltage between electrodes to cause a discharge followed by generating active species on the surface, and then introducing a functional group of the organic compound or graft-polymerizing a polymerizable organic compound.

An example of an organic compound in the organic compound-containing inert gas includes a polymerizable or non-polymerizable organic compound containing an oxygen atom, such as vinyl esters such as vinyl acetate and vinyl formate; acrylate such as glycidyl methacrylate; ethers such as vinyl ethyl ether, vinyl methyl ether, and glycidyl methyl ether; carboxylic acids such as acetic acid and formic acid; alcohols such as methyl alcohol, ethyl alcohol, phenol, and ethylene glycol; ketones such as acetone and methyl ethyl ketone; carboxylic esters such as ethyl acetate and ethyl formate; and acrylic acids such as acrylic acid and methacrylic acid. Among these, in terms of a modified surface that is less likely to be deactivated, i.e., the surface which has a long life, the vinyl esters, acrylates, and ketones are preferred, and vinyl acetate and glycidyl methacrylate are particularly preferred.

A concentration of the organic compound in the organic compound-containing inert gas varies depending on the type of organic compound and a type of fluororesin to be surface treated, but is usually 0.1 to 3.0% by volume, preferably 0.1 to 1.0% by volume, more preferably 0.15 to 1.0% by volume, and still more preferably 0.30 to 1.0% by volume. The discharge conditions may be appropriately selected depending on a degree of surface treatment of a target, the type of fluororesin, and the type of organic compound and its concentration. Usually, the discharge treatment is carried out in an amount of discharge in the range of 50 to 1, 500 W·min/m² and preferably 70 W·min/m² or more and 1, 400 W·min/m² or less. The treatment can be arbitrarily carried out at a treatment temperature in the range of 0° C. or higher and 100° C. or lower. The temperature is preferably 80° C. or lower due to concerns about elongation and wrinkles of the sheet.

### (Laminate)

The sheet of the present disclosure can be used by being stacked with another substrate as a sheet for printed wiring boards.

The sheet of the present disclosure can be stacked with metal foil and used as a sheet of a circuit board. The sheet may be used to form a laminate in which metal foil adheres to one or both sides of the aforementioned sheet. The present disclosure is also a metal-clad laminate including the aforementioned sheet as an essential layer and a metal foil layer on one or both sides thereof.

Examples of the metal foil to be used in the present disclosure include copper foil, gold foil, silver foil, platinum foil, and ruthenium foil. Of these, copper foil is preferred due to its low conductor loss.

The present disclosure is also a copper-clad laminate characterized in that copper foil adheres to one or both sides of the aforementioned sheet. As described above, the sheet of the present disclosure can be particularly suitably used in printed wiring board applications and can therefore be suitably used as a copper-clad laminate.

The copper foil described above preferably has an Rz of 2.0 μm or less. In other words, the sheet of the present disclosure is also excellent in adhesiveness to copper foil with high degree of smoothness of an Rz of 2.0 μm or less. Furthermore, the Rz value of at least a surface of the copper foil adhering to the aforementioned sheet is 2.0 μm or less and the Rz value of the other surface is not limited. The copper foil for use is preferably copper foil having a high degree of smoothness of an Rz of preferably 2.0 μm or less, more preferably 1.6 μm or less, and still more preferably 1.0 μm or less. The Rz is the sum of a value of the highest portion (maximum peak height: Rp) and a value of the deepest portion (maximum valley depth: Rv). The surface roughness is a ten-point average roughness stipulated in JIS-B0601. The Rz as used herein is the value measured using a surface roughness meter (product name: SURFCOM 470A, manufactured by Tokyo Seimitsu Co., Ltd.) with a measurement length of 4 mm.

A thickness of the copper foil is not limited, and is preferably in the range of 1 to 100 μm, more preferably in the range of 5 to 50 μm, and still more preferably 9 to 35 μm.

The copper foil is not limited, and specific examples thereof include rolled copper foil and electrolytic copper foil.

The copper foil having an Rz of 2.0 μm or less is not limited, and commercially available products can be used. An example of commercially available copper foil having an Rz of 2.0 μm or less includes electrolytic copper foil CF-T9DA-SV-18 (thickness 18 μm/Rz 0.85 μm) (manufactured by Fukuda Metal Foil Powder Co., Ltd.).

The copper foil may have been subjected to surface treatment in order to enhance the adhesive strength to the sheet of the present disclosure.

The surface treatment may be, but is not limited to, silane coupling processing, plasma processing, corona processing, UV processing, electron beam processing, and the like, with the plasma processing being preferred. A reactive functional group of the silane coupling agent is not limited, but from the viewpoint of adhesiveness to a resin substrate, the silane coupling agent preferably has at least one selected from an amino group, a (meth)acrylic group, a mercapto group, and an epoxy group, at an end of the agent. Also, a hydrolyzable group may be, but is not limited to, alkoxy groups such as a methoxy group and an ethoxy group. The copper foil to be used in the present disclosure may be copper foil in which an anti-corrosion layer (for example, an oxide film such as a chromate), a heat-resistant layer, or the like, has been formed.

Surface-treated copper foil having a surface treating layer with the silane compound described above on a surface of the copper foil can be produced by preparing a solution containing a silane compound and then surface-treating the copper foil with this solution.

The copper foil may have a roughening-treated layer on its surface from the viewpoint of enhancing the adhesiveness to a resin substrate. Incidentally, in a case in which roughening processing may deteriorate the performance required in the present disclosure, the number of roughened particles to be electrodeposited on a surface of the copper foil can be reduced if necessary, or the copper foil may be used in a manner not to undergo roughening processing.

From the viewpoint of improving various properties, one or more layers selected from the group consisting of a heat-resistant treatment layer, an anti-corrosion treatment layer, and a chromate treatment layer may be disposed between the copper foil and a surface treating layer. These layers may be each a single layer or a multilayer.

The metal-clad laminate of the present disclosure may be those further having a layer other than the metal foil and the sheet. The layer other than the metal foil and the sheet is preferably at least one selected from the group consisting of polyimide, modified polyimide, a liquid crystal polymer, polyphenylene sulfide, a cycloolefin polymer, polystyrene, an epoxy resin, bismaleimide, a polyphenylene oxide, a modified polyphenylene ether, a polyphenylene ether, and polybutadiene.

The layer other than these metal foil and sheet is not limited as long as it is composed of the aforementioned resins. Also, a thickness of the layer other than the metal foil and the sheet is preferably within the range of 12.5 to 260 μm.

In the metal-clad laminate of the present disclosure, a metal layer may be formed on one or both sides of a roll film. Examples of a method for forming the metal layer include a method for stacking metal foil on a surface of the roll film (for allowing metal foil to adhere thereon), a vapor deposition method, a plating method, and the like. An example of the method for stacking metal foil includes a method using heat press. An example of a heat press temperature upon heat press includes a temperature between the melting point of the sheet −150° C. and the melting point of the sheet +40° C. A heat press time is, for example, 1 to 30 minutes. The pressure of the heat press is 0.1 to 10 MPa, thereby the laminate can be produced.

The metal-clad laminate of the present disclosure is not limited in its application and is used as a circuit board. A printed circuit board is a platy component that electrically connects electronic components such as a semiconductor and a capacitor chip while simultaneously arranging and fixing them in a limited space. The configuration of a printed circuit board formed of the metal-clad laminate of the present disclosure is not limited. The printed circuit board may be any one of a rigid board, a flexible board, or a rigid-flexible board. The printed circuit board may be any one of a single-sided board, a double-sided board, or a multilayer board (such as a build-up board). In particular, a flexible board or a rigid board can be suitably used. It is particularly suitable for use as a printed circuit board for high frequencies of 10 GHz or higher.

A circuit board is not limited and can be produced by a general method using the aforementioned metal-clad laminate.

In the metal-clad laminate of the present disclosure, a metal foil layer may be formed on one or both sides of a rolled sheet. Examples of a method for forming the metal foil layer include a method for stacking the metal foil on a surface of the rolled sheet (for allowing the metal foil to adhere thereon), a vapor deposition method, and a plating method.

An example of the method for stacking the metal foil include a method such as a heat press. An example of a heat press temperature includes a temperature from the melting point of the sheet −150° C. to the melting point of the sheet +40° C. A heat press time is, for example, 1 to 30 minutes.

It is achieved, for example, in that the sheet described above and metal foil are stacked, heated at 180 to 390° C., and press-formed at a pressure of 0.5 to 5 MPa under a vacuum or in an inert gas atmosphere. A method for producing a copper-clad laminate is characterized in that the sheet described above and metal foil are stacked, heated at 180 to 390° C., and press-formed at a pressure of 0.5 to 5 MPa under a vacuum or in an inert gas atmosphere.

In obtaining the configuration of the aforementioned laminate, the sheet of the present disclosure is to be used with copper foil allowed to adhere to one or both surfaces of the sheet. As described above, the sheet of the present disclosure has excellent adhesiveness. Therefore, it also has excellent adhesiveness to copper foil having a high smoothness of Rz of 2.0 μm or less.

A surface of copper foil to be used in the circuit board conventionally has a certain degree of unevenness in order to ensure an adhesiveness with an insulating layer. However, in high-frequency applications, the presence of unevenness on a surface of the copper foil causes a loss of an electrical signal, which is thereby not preferable. The laminate described above can obtain suitable adhesiveness even to copper foil having a high smoothness, and is a laminate that can be suitably used as a circuit board.

A laminate for circuit boards is also a laminate characterized by having a metal foil layer and the aforementioned sheet. The laminate described above may further have a substrate layer. The substrate layer is not limited but preferably has a fabric layer composed of glass fibers and a resin film layer.

The fabric layer composed of glass fibers described above is a layer composed of glass cloth, a glass nonwoven fabric, or the like. Commercially available glass cloth can be used, and glass cloth treated with a silane coupling agent is preferred in order to enhance the affinity with a fluororesin. Examples of glass cloth materials include E-glass, C-glass, A-glass, S-glass, D-glass, NE-glass, and low-dielectric-constant glass, and preferred are E-glass, S-glass, and NE-glass due to their availability. A weaving method may be either plain weave or twill weave. The glass cloth typically has a thickness of 5 to 90 μm, preferably 10 to 75 μm, but it is preferable to use one thinner than the sheet to be used.

The laminate described above may also use a glass nonwoven fabric as a fabric layer composed of glass fibers. The glass nonwoven fabric is a fabric in which glass staple fibers are bonded together with a small amount of binder compound (resin or inorganic material), and a fabric maintaining its shape by entangling glass staple fibers without using a binder compound, which are commercially available. The diameter of the glass staple fiber is preferably 0.5 to 30 μm and the fiber length is preferably 5 to 30 mm. Specific examples of the binder compound include resins such as an epoxy resin, an acrylic resin, cellulose, a polyvinyl alcohol, and a fluororesin, as well as an inorganic substance such as a silica compound. The amount of binder compound used is typically 3 to 15% by mass based on the amount of glass staple fiber. Examples of materials for the glass staple fiber include E-glass, C-glass, A-glass, S-glass, D-glass, NE-glass, and low-dielectric-constant glass. A thickness of the glass nonwoven fabric is typically 50 μm to 1,000 μm, preferably 100 to 900 μm. Incidentally, the thickness of the glass nonwoven fabric in the present application refers to the value measured in accordance with JIS P8118:1998 using a digital gauge DG-925 (load 110 grams and face diameter 10 mm) manufactured by ONO SOKKI Co., Ltd. In order to enhance the affinity with a fluororesin, the glass nonwoven fabric may be subjected to treatment with a silane coupling agent.

Many glass nonwoven fabrics have an extremely high degree of porosity of 80% or more, so that it is preferable to use one thicker than a sheet composed of a fluororesin and then use it by compression thereof under pressure.

The fabric layer composed of glass fibers may also be a layer stacked with glass cloth and a glass nonwoven fabric. This allows the properties of each material to be combined to provide optimal properties. The fabric layer composed of glass fibers may be in the form of a prepreg impregnated with a resin.

In the laminate, a fabric layer composed of glass fibers and the sheet may be bonded at their interface, or the sheet may be partially or entirely impregnated into the fabric layer composed of glass fibers.

Furthermore, the laminate may be a laminate in which the fabric layer composed of glass fibers has been impregnated with a fluororesin composition to fabricate a prepreg. The laminate may also be a laminate in which the prepreg thus obtained has been stacked with the sheet of the present disclosure. In this case, the fluororesin composition to be used upon fabrication of the prepreg is not limited, and the sheet of the present disclosure may also be used.

A resin film to be used as the substrate layer described above is preferably a heat-resistant resin film or a thermosetting resin film. Examples of the heat-resistant resin film include polyimide, modified polyimide, a liquid crystal polymer, and polyphenylene sulfide. Examples of the thermosetting resin include an epoxy resin, bismaleimide, a polyphenylene oxide, a modified polyphenylene ether, a polyphenylene ether, and polybutadiene.

The heat-resistant resin film and thermosetting resin film may also include a reinforcing fiber. The reinforcing fiber is not limited, and examples thereof include glass cloth in particular a low-dielectric-constant fiber.

The characteristics such as the dielectric properties, coefficient of linear expansion, and water absorption of the heat-resistant resin film and thermosetting resin film are not limited, and for example, the dielectric constant at 20 GHz is preferably 3.8 or less, more preferably 3.4 or less, and still more preferably 3.0 or less. The dielectric loss tangent at 20 GHz is preferably 0.0030 or less, more preferably 0.0025 or less, and still more preferably 0.0020 or less. The coefficient of linear expansion is preferably 100 ppm/° C. or less, more preferably 70 ppm/° C. or less, and still more preferably 40 ppm/° C. or less. The water absorption is preferably 1.0% or less, more preferably 0.5% or less, and still more preferably 0.1% or less.

The metal-clad laminate of the present disclosure is not limited on its application and is used as a circuit board. The present disclosure is also a circuit board having the metal-clad laminate described above.

The circuit board is a platy component that electrically connects electronic components such as a semiconductor and a capacitor chip while simultaneously arranging and fixing them in a limited space. The configuration of the circuit board formed of the sheet or metal-clad laminate of the present disclosure is not limited. The circuit board may be any one of a rigid board, a flexible board, or a rigid-flexible board. The circuit board may be any one of a single-sided board, a double-sided board, or a multilayer board (such as a build-up board). In particular, it can be suitably used for a flexible board and a rigid board. In a case in which the sheet of the present disclosure does not include a glass fiber or cloth composed of glass fibers, it is suitable for use in a flexible board.

It is particularly suitable for use as a printed circuit board for high frequencies of 10 GHz or higher.

In the present disclosure, examples of the high-frequency circuit include not only a circuit that transmits only high-frequency signals, but also a circuit in which a transmission line transmitting signals other than high-frequency signals is also arranged on the same plane, such as a transmission line that converts high-frequency signals to low-frequency signals and outputs the generated low-frequency signals to an outside, a transmission line that supplies power supplied to drive high-frequency compatible components, and the like. Also, it can also be used as a circuit board for antennas, filters, and the like.

The present disclosure is also an antenna formed of the circuit board. It is particularly suitable for use as a millimeter wave antenna for mobility applications such as automobiles and aircraft.

The circuit board is not limited and can be produced by a general method using the aforementioned metal-clad laminate.

The sheet and metal-clad laminate of the present disclosure are used as electrical and electronic components. Examples thereof include antennas to be used in electronic equipment and communication equipment such as an ETC, GPS, wireless LAN, and a mobile phone, a high-speed transmission connector, a CPU socket, millimeter-wave and quasi-millimeter-wave radars such as collision prevention radars, an RFID tag, a capacitor, an inverter component, a coating material of cables, an insulating material for a secondary battery such as a lithium-ion battery, and a speaker diaphragm.

Examples of the high-speed communication compatible substrate include a base station antenna substrate, an antenna distribution substrate, a substrate for an RRH (Remote Radio Head), which is a radio portion of a wireless base station, a substrate for a control portion or a baseband portion (BBU: Base Band Unit) of a wireless base station, a high-speed communication transceiver substrate, an RNC (Radio Network Controller) substrate, a high-speed transmitter substrate, a high-speed receiver substrate, a substrate for high-speed signal multiplexing circuits, a substrate for Wi-Fi using a 60 GHz band, and a data transfer substrate to be used in data center servers. Other examples of the high-speed communication compatible substrate include an antenna substrate, such as a substrate for massive MIMO antennas for high-capacity communication required by standards beyond 5G. A further example thereof also includes a receiving antenna for wireless power transmission by microwave space propagation. The sheet of the present disclosure has a favorable adhesiveness with unroughened copper foil, which has a low transmission loss, so that in a case in which a copper-clad laminate including the sheet of the present disclosure and unroughened copper foil is processed to produce an antenna, the gain is improved, making it particularly suitable for antennas.

The sheet of the present disclosure can be used not only as an insulator for substrates, but also as an insulating material for signal line covering. For example, it can be used as materials for insulating coating (for example, insulating tubes) for a waveguide that transmits high-speed signals, a QSFP cable for high-speed LANs, a coaxial cable compatible for high-speed communication (for example, SFP+a cable, QSFP+a cable, and the like), a coaxial cable for low losses, and the like.

When using such high frequencies, a material to be used in an electrical component such as a connector and communication equipment such as a casing, requires stable electrical properties, such as a low relative dielectric constant (εr) and a low dielectric loss tangent (tan δ). The sheet of the present disclosure can also be used as an insulating material for such materials.

The sheet of the present disclosure can also be used as an insulating material for connector printed wiring boards that needs to be soldered. The sheet of the present disclosure has excellent heat resistance, making it unlikely to cause a problem even at an elevated temperature upon soldering.

In a dielectric waveguide line, a material with a low dielectric loss is required in order to transmit high-frequency millimeter waves or submillimeter waves with a low loss. The sheet of the present disclosure can also be used as an insulation material for dielectric waveguide lines that transmit millimeter waves or submillimeter waves. Examples of the dielectric waveguide line include a cylindrical dielectric line, a rectangular dielectric line, an elliptical dielectric line, a tubular dielectric line, an image line, an insular image line, a trapped image line, a rib guide, a strip dielectric line, an inverted strip line, an H guide, and a non-radiative dielectric line (NRD guide).

In the present disclosure, the mobility refers to all means and methods related to movement and transportation, including automobiles in general, such as a private car, a bus, a taxi, and a truck, as well as two-wheeled vehicles such as a motorcycle, a bicycle, and a moped, a train, a senior car, and a compact one-seater personal mobility vehicle. Also, the mobility is not necessarily limited to means such as vehicles that move on land and may be means that move through the air or water.

A change in dielectric properties of a dielectric due to change in temperature of the environment in which the dielectric is used has a significant impact on circuits and antenna performance. Therefore, the dielectric properties are preferably not changed significantly with change in temperature. The present disclosure provides a sheet having a small change in relative dielectric constant with change in temperature in order to minimize the effect on antenna performance.

The present disclosure is a sheet comprising two or more fillers, wherein a rate of change in relative dielectric constant is 0.020 or less in a temperature range of −50 to 150° C.

The sheet preferably has a coefficient of linear expansion (CTE) of 70 ppm/K or less.

The sheet preferably has a dielectric loss tangent value at 10 GHz of 0.0015 or less.

The sheet preferably has a thickness of 5 to 250 μm.

The sheet preferably includes a fluororesin.

The fluororesin is preferably polytetrafluoroethylene.

The filler preferably has a band gap of 2 eV or more.

The content of the filler is preferably 30% by mass or more based on the total mass of the sheet.

The filler preferably includes at least two selected from the group consisting of silica, alumina, boron nitride, and zirconium oxide.

The filler is preferably two of silica and alumina.

The silica is preferably a spherical particle.

The silica is preferably a silica particle treated with a silane coupling agent.

The silane coupling agent preferably has an aminopropyl group.

The silica particle preferably has an average particle size of 10 μm or less.

The alumina preferably has an average particle size of 10 μm or less.

The amount of the alumina compounded is preferably 10 to 50% by mass based on the total amount of alumina and silica.

The present disclosure is also a method for producing the sheet, comprising mixing a fluororesin and a filler to form a film.

The present disclosure is also a method for producing the aforementioned sheet, comprising forming a film using a composition composed substantially of a fluororesin particle and a filler particle, the filler particle including at least a silica particle and an alumina particle.

The present disclosure is also a metal-clad laminate, including the sheet as an essential layer, and a metal foil layer on one or both sides of the sheet.

The metal foil is preferably copper.

The present disclosure is also directed to a circuit board, including the metal-clad laminate.

The present disclosure is also directed to an antenna formed of the circuit board.

The antenna is preferably a millimeter wave antenna for mobility applications.

The sheet disclosed herein that has a small change in relative dielectric constant with change in temperature thereby provides an excellent effect of allowing the performance not to be changed due to change in temperature in applications exposed to an environment with a large temperature change, such as antennas for millimeter wave radars for mobility applications.

### EXAMPLES

The present disclosure will now be described in detail below based on the following Examples. In the following Examples, the terms “parts” and “%” represent “parts by mass” and “% by mass,” respectively, unless otherwise specified.

### Examples 1 to 9 and Comparative Examples 1 to 3

### Method for Fabricating Sheet (Paste Extrusion Forming)

A predetermined amount of PTFE powder (average particle size: 500 μm, apparent density: 460 g/L, and standard specific gravity: 2.17), silica particles (SC6500-SQ, average particle size: 2.1 μm, manufactured by Admatechs Co., Ltd.), and alumina particles (LS-210B (average particle size: 3.2 μm) or LS-110F (average particle size: 1.13 μm), manufactured by Nippon Light Metal Co., Ltd.) were weighed out in the proportions shown in Table 1 and mixed in a mixer in the presence of dry ice. The temperature during mixing was kept −10° C. or lower.

To the resulting mixed powder was added oil (Isopar H) in a proportion of 21 wt %, mixed and aged for approximately 5 hours.

The aged composition was preliminarily formed under the conditions of a pressure of 3 MPa, and the preformed article was extruded under the conditions of 40° C. and 50 mm/min to obtain an extruded sample.

The extruded sample was rolled with two rolls (a roll gap was set to 500 to 80 μm) to obtain a sample with a film thickness of 125 μm, which was then dried at 200° C. for 2 hours and sintered at 360° C. for 15 minutes to obtain a sheet.

### Comparative Example 4

A sheet was obtained in the same manner as in Examples 1 to 9 and Comparative Examples 1 to 3, except that zinc oxide particles (DW-4, average particle size: 4 μm, manufactured by HAKUSUI TECH CO., LTD.) were used instead of the alumina particle.

### Example 10

### Method for Fabricating Sheet (Powder Rolling Forming)

PTFE powder (average particle size: 500 μm, apparent density: 460 g/L, and standard specific gravity: 2.17), silica particles (SC6500-SQ, average particle size: 2.1 μm, manufactured by Admatechs Co., Ltd.), and alumina particles (LS-210B (average particle size: 3.2 μm) or LS-110F (average particle size: 1.13 μm), manufactured by Nippon Light Metal Co., Ltd.) were weighed out so that their mass ratios were those shown in Table 1 and stirred twice for 30 seconds at room temperature with a Wonder Crusher at setting 6.

The resulting mixture was rolled with two rolls (the roll gap was set to 100 μm and a roll temperature was 100° C.) to obtain a sample with a film thickness of 130 μm, which was then sintered at 360° C. for 15 minutes to obtain a sheet.

Each sample obtained was evaluated based on the following criteria.

### [Relative Dielectric Constant (Dk) of Sheet]

Using a split-cylinder dielectric constant/dielectric loss tangent measuring apparatus (manufactured by EMLab P&K), a Dk was measured at 10 GHz at an increment of 10° C. from −50° C. to 150° C.

The rate of change from −50° C. to 150° C. was calculated base on the difference between the maximum value and the minimum value of measured Dk values.

### [Dielectric Loss Tangent (Df) of Sheet]

Using a split-cylinder dielectric constant/dielectric loss tangent measuring apparatus (manufactured by EMLab P&K), a Df was measured at 20° C. and 10 GHz.

### [Coefficient of Linear Expansion (CTE)]

A TMA measurement was performed in tension mode using a TMA-7100 (manufactured by Hitachi High-Tech Science Corporation). A sheet cut to dimensions of 20 mm in length, 5 mm in width, and 150 μm in thickness was used as a sample piece. The distance between chucks was set to 10 mm. A coefficient of linear expansion was determined based on the displacement amount of the sample measured during heating from 0 to 150° C. at a heating rate of 2° C./min while a load of 49 mN was applied.

The results are shown in Table 1.

TABLE 1

| | | | | | Rate of change in relative | | |
|---|---|---|---|---|---|---|---|
| | | Surface treatment of silica with | | Type and amount | dielectric constant in the | Dielectric | |
| | Silica | silane coupling agent and | PTFE | of filler other than | temperature range of −50° | loss | |
| | amount | amount treated | amount | silica | C. to 150° C. | tangent | CTE |
| Comparative | 60 wt % | None | 40 wt % | None | 0.023 | 0.0004 | 54 |
| Example 1 | | | | | | | |
| Comparative | 60 wt % | Aminopropyl treatment, 1 wt % | 40 wt % | None | 0.021 | 0.0007 | 31 |
| Example 2 | | | | | | | |
| Example 1 | 48 wt % | Aminopropyl treatment, 0.2 wt % | 40 wt % | LS-210B, 12 wt % | 0.015 | 0.0007 | 42 |
| Example 2 | 48 wt % | Aminopropyl treatment, 0.2 wt % | 40 wt % | LS-110 F, 12 wt % | 0.016 | 0.0008 | 42 |
| Example 3 | 40 wt % | Aminopropyl treatment, 0.2 wt % | 40 wt % | LS-210B, 20 wt % | 0.016 | 0.0007 | 46 |
| Example 4 | 40 wt % | Aminopropyl treatment, 0.2 wt % | 40 wt % | LS-110 F, 20 wt % | 0.016 | 0.0008 | 45 |
| Example 5 | 48 wt % | None | 40 wt % | LS-210B, 12 wt % | 0.015 | 0.0008 | 44 |
| Example 6 | 48 wt % | None | 40 wt % | LS-110 F, 12 wt % | 0.015 | 0.0009 | 43 |
| Example 7 | 52 wt % | Aminopropyl treatment, 0.2 wt % | 40 wt % | LS-210B, 8 wt % | 0.019 | 0.0007 | 39 |
| Example 8 | 52 wt % | Aminopropyl treatment, 0.2 wt % | 40 wt % | LS-110 F, 8 wt % | 0.018 | 0.0008 | 39 |
| Example 9 | 38 wt % | Aminopropyl treatment, 0.2 wt % | 50 wt % | LS-210B, 12 wt % | 0.016 | 0.0006 | 58 |
| Example 10 | 48 wt % | Aminopropyl treatment, 0.2 wt % | 40 wt % | LS-210B, 12 wt % | 0.016 | 0.0006 | 41 |
| Comparative | 60 wt % | Aminopropyl treatment, 0.2 wt % | 40 wt % | None | 0.021 | 0.0007 | 36 |
| Example 3 | | | | | | | |
| Comparative | 50 wt % | Aminopropyl treatment, 0.2 wt % | 40 wt % | DW-4, 10 wt % | 0.044 | 0.015 | 46 |
| Example 4 | | | | | | | |

The sheet obtained in Example 1 underwent “sheet surface treatment,” “XPS measurement of the sheet surface,” and “peel strength measurement” under the following conditions. As a result, it was confirmed that the XPS measurement demonstrated the following element composition (atomic %): C1s: 43.4, N1s: 2.8, O1s: 7.1, F1s: 43.3, Si2p: 1.2. The sheet exhibited the high degree of peel strength of 11 N/cm, also confirming high degree of adhesiveness.

### [Sheet Surface Treatment]

A sheet was disposed between the upper and lower electrodes in a processing chamber (direct plasma surface treatment machine, manufactured by AIR WATER INC.) equipped with the upper electrode and the lower electrode, and the processing chamber was filled with a mixed gas atmosphere of argon, helium, nitrogen, and oxygen, and a surface of the sheet was subjected to discharge plasma processing for the processing time of 36 seconds.

Each element composition of the surface-treated sheet was measured using XPS.

### [XPS Measurement of Sheet Surface]

Measurement was performed using a scanning X-ray photoelectron spectroscopy (XPS/ESCA) apparatus, PHI5000 VersaProbe II (manufactured by ULVAC-PHI, INC.).

### [Peel Strength Measurement]

After the surface treatment, pieces of copper foil (CF-T9DA-SV-18, Rz=0.85 μm and Rq=0.05 μm, manufactured by Fukuda Metal Foil Powder Co, Ltd.) were overlapped on top and bottom of the sheet so that the treated surface of the copper foil was in close contact with the sheet, and the sheet was then pressurized and heated in a vacuum heat press (360° C., 2.5 MPa, and 300 s) to fabricate a sample.

The obtained sample was cut into a strip with a width of 10 mm, and a Tensilon universal testing machine (manufactured by Shimadzu Corporation) was used to measure peel strength by pulling a portion not adhering to the sheet, of the strip sample at a speed of 50 mm per minute while being held with the top and bottom chucks of the Tensilon, then to take the obtained value as the peel strength.

The results described above reveal that the sheets of the present disclosure exhibit a low rate of change in relative dielectric constant of 0.020 or less in the temperature range of −50 to 150° C. while maintaining the low dielectric loss tangent and low CTE and are excellent in adhesiveness to copper foil, resulting in the sheet exhibiting excellent performance in high-frequency printed wiring boards, particularly, as a substrate to be used in antennas for millimeter wave radars for mobility applications.

### INDUSTRIAL APPLICABILITY

The sheets of the present disclosure are particularly suitable for use in high-frequency printed circuit boards.

1. A sheet comprising a fluororesin and two or more fillers, wherein
a rate of change in relative dielectric constant is 0.020 or less in a temperature range of −50 to 150° C., and
the fillers consist essentially of fillers having a band gap of 4 eV or more.

2. The sheet according to claim 1, wherein the sheet has a coefficient of linear expansion (CTE) of 70 ppm/° C. or less.

3. The sheet according to claim 1, having a dielectric loss tangent value at 10 GHz of 0.0015 or less.

4. The sheet according to claim 1, having a thickness of 5 to 250 μm.

5. The sheet according to claim 1, wherein the fluororesin is polytetrafluoroethylene.

6. The sheet according to claim 1, wherein a content of the filler is 30% by mass or more based on a total mass of the sheet.

7. The sheet according to claim 1, wherein the filler comprises at least two selected from the group consisting of silica, alumina, boron nitride, and zirconium oxide.

8. The sheet according to claim 1, wherein the filler is two of silica and alumina.

9. The sheet according to claim 7, wherein the silica is a spherical particle.

10. The sheet according to claim 7, wherein the silica is a silica particle treated with a silane coupling agent.

11. The sheet according to claim 7, wherein the silica particle has an average particle size of 10 μm or less.

12. The sheet according to claim 7, wherein the alumina has an average particle size of 10 μm or less.

13. A method for producing the sheet according to claim 1, comprising mixing a fluororesin and a filler to form a film.

14. A method for producing the sheet according to claim 1, comprising forming a film using a composition composed substantially of a fluororesin particle and a filler particle, the filler particle including at least a silica particle and an alumina particle.

15. A metal-clad laminate comprising
the sheet according to claim 1 as an essential layer, and a metal foil layer on one or both sides of the sheet.

16. The metal-clad laminate according to claim 15, wherein the metal foil is copper.

17. A circuit board comprising the metal-clad laminate according to claim 15.

18. An antenna formed of the circuit board according to claim 17.

19. The antenna according to claim 18, being a millimeter wave antenna for mobility applications.

20. The sheet according to claim 1, which is for a circuit board.
